(19) United States
(12) Patent Application Publication
(10) Pub. No.: US 2026/0249420 A1
(43) Pub. Date: Aug. 27, 2026

(54) POLISHING PAD, POLISHING METHOD, AND METHOD FOR MANUFACTURING SEMICONDUCTOR

(71) Applicant: KURARAY CO., LTD., Kurashiki-shi, Okayama (JP)

(72) Inventor: Azusa SUNAYAMA, Kurashiki-shi, Okayama (JP)

(73) Assignee: KURARAY CO., LTD., Kurashiki-shi, Okayama (JP)

(21) Appl. No.: 19/489,651

(22) PCT Filed: Jun. 11, 2024
(86) PCT No.: PCT/JP2024/021113

§ 371 Date: Dec. 3, 2025

(30) Foreign Application Priority Data
Jun. 12, 2023 (JP) 2023-096439

(51) Int. Cl. B24B 37/24; B24B 37/32; H10P 52/40

(52) U.S. Cl. CPC B24B 37/24; B24B 37/32; H10P 52/402

(57) ABSTRACT

The present invention relates to: a polishing pad including a polishing layer having a circular polishing surface, the polishing layer having one or more grooves α that each have a first end Eα1 and a second end Eα2 which is closer to the outer circumference of the polishing surface than the first end Eα1 is and that each extend from the first end Eα1 toward the second end Eα2, the first end Eα1 of each groove α being present in an area (1) that is a range of 70.0 to 99.0% relative to the radius of the polishing surface from the center of the polishing surface, the second end Eα2 of each groove α being not connected to the outer circumference of the polishing layer; and a polishing method in which the polishing pad is used.

### TECHNICAL FIELD

The present invention relates to a polishing pad, a polishing method, and a method for producing a semiconductor.

### BACKGROUND ART

For mirror-finishing a material for substrates of semiconductors, silicon wafers, and the like; or a glass or the like which is a material for hard disks, liquid crystal displays, and lenses, and for flattening unevenness of insulating films, metal films, and the like in a manufacturing process of semiconductor devices, chemical-mechanical polishing (CMP) has conventionally been used in which a material to be polished is polished by pressing the material against a polishing pad while dropwise adding a polishing slurry (hereinafter also referred to simply as a slurry) to a polishing surface of the polishing pad.

In a polishing pad for CMP, for example, grooves, such as a spiral groove, concentric grooves, a latticed groove, or radial grooves are formed, for the purpose of allowing the polishing surface to uniformly retain the slurry, discharging polishing swarf, and preventing the material to be polished from damage due to adsorption.

For example, PTL 1 discloses a polishing pad that includes a polishing layer having a circular polishing surface, the polishing surface having a central area that is a range of 0 to 10% and a peripheral area that is a range of 90 to 100% relative to the radius from the center of the polishing surface, the polishing layer having at least one spiral groove or concentric grooves including a plurality of concentrically arranged annular grooves, the spiral groove or concentric grooves being disposed from the central area to the peripheral area, and further having radial grooves including at least two segment grooves that each extend from the central area toward the peripheral area, the center of the spiral groove, the center of the concentric grooves, and the center of the radial grooves being present in the central area, the segment grooves having an average length of 30 to 65% of the radius of the polishing surface and having a first end in an area of a distance of 5 to 10% and a second end in an area of a distance of 35 to 70% relative to the radius of the polishing surface from the center of the radial groove, a sectional area Sa (mm²) which is the average of sectional areas of cross sections in a direction perpendicular to the length direction of the segment grooves and a sectional area Sb (mm²) which is the average of sectional areas of cross sections in a direction perpendicular to the tangential direction of the spiral groove or the concentric groove satisfying 0.1≤Sb/Sa<1.0.

In addition, for example, PTL 2 discloses a polishing pad including a polishing layer, the polishing layer having at least two concentric grooves, the innermost concentric groove thereof being defined as a first concentric circle, the outermost concentric groove thereof being defined as a second concentric circle, when the distance from the center of the polishing layer to the innermost position of the first concentric circle is taken as W1, the distance from the outermost position of the second concentric circle to the edge of the polishing layer is taken as W3, and the radius of the polishing layer is taken as R, a first polishing area being the inner area of the first concentric circle, a second polishing area being the area of a distance W2=R−W1−W3 between the first concentric circle and the second concentric circle, a third polishing area being an area of a distance W3 between the second concentric circle and the edge of the grinding layer, the third polishing area further having a third groove, the outer end of the third groove being connected to the edge of the polishing layer, the inner end of the third groove being disposed within the second polishing area.

Furthermore, PTL 3 discloses a polishing pad for CMP having a plurality of grooves on a surface thereof, and having concentric pad circles (circular grooves) whose axis is the axis of rotation of a rotating pad, the plurality of grooves being substantially perpendicular to a first pad circle, the deviation of the radial component of the plurality of grooves becomes substantially greater than the circumferential deviation as the plurality of grooves extends from the center of the pad toward the outside of the pad.

### CITATION LIST

### Patent Literature

PTL 1: WO 2023/013576
PTL 2: CN 112809550 A
PTL 3: WO 2006/093670

### SUMMARY OF INVENTION

### Technical Problem

In CMP, a polishing pad that achieves a higher polishing rate and a higher polishing accuracy is desired. However, according to studies of the present inventors, it has been difficult to achieve both a high polishing rate and a high polishing uniformity of an area vicinity to the edge (hereinafter also referred to as “edge area”) of a material to be polished.

The present invention has been made in view of the above problem of the related art, and has an object to provide a polishing pad that achieves a high polishing rate and a superior polishing uniformity in an edge area of a material to be polished in CMP, a polishing method in which the polishing pad is used, and a method for producing a semiconductor in which the polishing method is used.

### Solution to Problem

The present inventors have focused on improvement of the uniformity of slurry distribution in a polishing area, and have found that a polishing pad having a specific groove in a polishing layer can solve the above problem, thus completing the present invention.

The present invention relates to the following [1] to [15].

[1] A polishing pad including a polishing layer having a circular polishing surface,
the polishing layer having at least one groove α that has a first end Eα1 and a second end Eα2 which is closer to an outer circumference of the polishing surface than the first end Eα1 is and that extends from the first end Eα1 toward the second end Eα2,
the first end Eα1 of the groove α being present in an area (1) that is a range of 70.0 to 99.0% relative to a radius of the polishing surface from a center of the polishing surface,
the second end Eα2 of the groove α being not connected to the outer circumference of the polishing layer.
   [2] The polishing pad according to the above [1], in which the first end Eα1 of the groove α is present in an area of 70.0 to 95.0% relative to the radius of the polishing surface from the center of the polishing surface.
   [3] The polishing pad according to the above [1] or [2], in which the second end Eα2 of the groove α is present in an area of 85.0 to 99.9% relative to the radius of the polishing surface from the center of the polishing surface.
   [4] The polishing pad according to any one of the above [1] to [3], in which a number of the grooves α is 2 to 36.
   [5] The polishing pad according to any one of the above [1] to [4], in which the groove α has a linear shape.
   [6] The polishing pad according to any one of the above [1] to [5], in which the polishing layer further has a reference recess β,
the reference recess β being a spiral, annular, or latticed reference groove β1 or reference holes β2 including a plurality of holes.
   [7] The polishing pad according to the above [6], in which the polishing layer has the reference groove β1 and the groove α intersects the reference groove β1 at least at one point.
   [8] The polishing pad according to the above [6] or [7], in which the groove α has a depth that is 0.5 to 2.5 times a depth of the reference groove β1.
   [9] The polishing pad according to any one of the above [1] to [8], in which the polishing layer further has at least one groove γ that has a first end Eγ1 and a second end Eγ2 which is closer to the outer circumference of the polishing surface than the first end Eγ1 is and that extends from the first end Eγ1 toward the second end Eγ2,
the first end Eγ1 of the groove γ being present in an area (2) that is a range of less than 70.0% relative to the radius of the polishing surface from the center of the polishing surface.
   [10] The polishing pad according to the above [9], in which the first end Eα1 of the groove α is closer to the outer circumference of the polishing surface than the second end Eγ2 of the groove γ is.
   [11] The polishing pad according to the above [10], in which a difference between a distance A from the center of the polishing surface to the first end Eα1 of the groove α and a distance B from the center of the polishing surface to the second end Eγ2 of the groove γ [distance A−distance B] is 8.0 to 50.0% relative to the radius of the polishing surface.
   [12] The polishing pad according to any one of the above [9] to [11], in which a length of the groove α is 5.0 to 100.0% relative to a length of the groove γ.
   [13] The polishing pad according to any one of the above [9] to [12], in which at least one of the groove α and the groove γ has a linear shape.
   [14] A polishing method including polishing a material to be polished by using the polishing pad according to any one of the above [1] to [13], the groove α being disposed under a retainer ring that surrounds the material to be polished.
   [15] A method for producing a semiconductor, the method including a step of polishing a semiconductor material by the polishing method according to the above [14].

### Advantageous Effects of Invention

According to the present invention, it is possible to provide a polishing pad for achieving a high polishing rate and a superior polishing uniformity in an edge area of a material to be polished in CMP, a polishing method in which the polishing pad is used, and a method for producing a semiconductor in which the polishing method is used.

### BRIEF DESCRIPTION OF DRAWINGS

FIG. 1 is a schematic plan view of a polishing pad 10 which is an embodiment of the polishing pad of the present invention.

FIG. 2 is a schematic plan view for explaining an area of a polishing surface of the polishing pad 10.

FIG. 3 is schematic sectional views representing shapes of cross sections in the direction perpendicular to the length direction of grooves.

FIG. 4 is a schematic sectional view representing a shape of a cross section in the direction perpendicular to the length direction of a groove.

FIG. 5 is a schematic plan view of a polishing pad 20 which is an embodiment of the polishing pad of the present invention.

FIG. 6 is a schematic plan view for explaining areas of a polishing surface of the polishing pad 20.

FIG. 7 is a schematic sectional view in the thickness direction of the polishing pad 10.

FIG. 8 is an explanatory drawing for explaining CMP.

FIG. 9(a) is a schematic plan view representing the position of a polishing head in CMP and FIG. 9(b) is a schematic sectional view of the polishing head and a polishing layer.

### DESCRIPTION OF EMBODIMENTS

The present invention will be described based on an example of embodiments of the present invention. However, the embodiment shown below is an example for embodying the technical idea of the present invention, and the present invention is not to be limited to the following description.

The aspect in which any matters in this Description are selected or combined is also encompassed in the present invention.

In this Description, any preferred definition can be arbitrarily selected, and a combination of preferred definitions is more preferred.

In this Description, a mention to “XX to YY” means “XX or more and YY or less”.

In this Description, regarding a preferred numerical range (for example, a range of a content or the like), any of upper limits and any of lower limits stepwise mentioned can be independently combined. For example, based on the mention to “preferably 10 to 90, and more preferably 30 to 60”, “the preferred lower limit (10)” and “the more preferred upper limit (60)” may be combined into “10 to 60”.

### [Polishing Pad]

Hereinafter, a polishing pad of this embodiment will be explained with reference to the drawings.

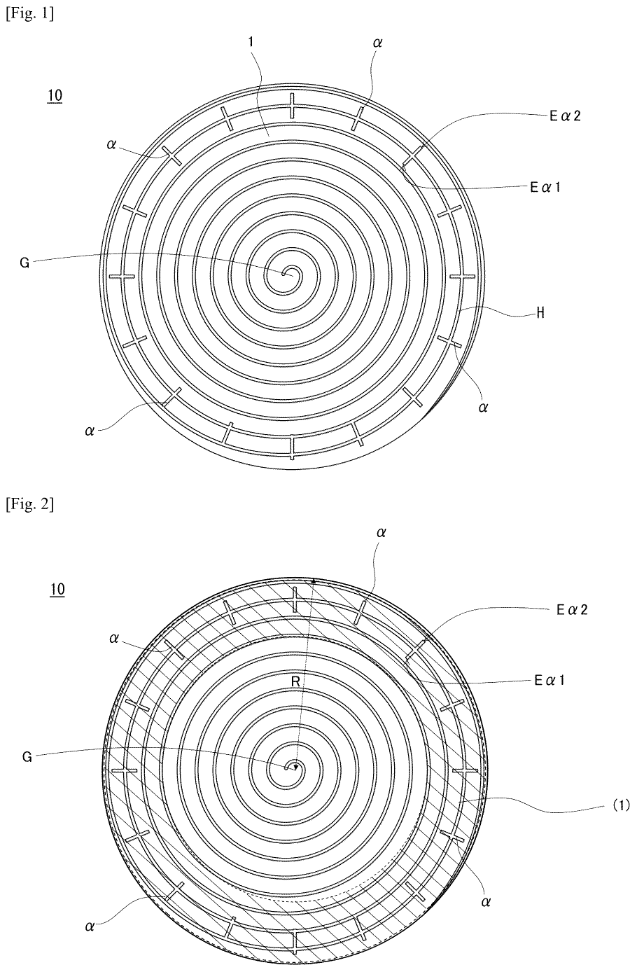

FIG. 1 is a schematic plan view for explaining a polishing pad 10 which is an example of the polishing pad of this embodiment.

In the polishing pad 10, a polishing surface of a polishing layer 1 has a circular shape.

The polishing layer 1 has 16 grooves α that each have a first end Eα1 and a second end Eα2 which is closer to the outer circumference of the polishing surface than the first end Eα1 is and that each extend from the first end Eα1 toward the second end Eα2.

The polishing layer 1 further has one spiral groove H that has a spiral center at the center G of the polishing surface.

The 16 grooves α each have a linear shape and are radially formed at equal intervals in the polishing surface outer circumference direction with the radial center thereof positioned at the center G of the polishing surface.

In the polishing pad 10, a part with no grooves α and no spiral groove H formed acts as a land area that is to come in contact with and polish a surface to be polished of a material to be polished.

FIG. 2 is an explanatory drawing for explaining an area in the polishing surface of the polishing pad 10.

In the polishing pad 10, a hatched area which is a range of 70.0 to 99.0% relative to the radius R of the polishing surface from the center G of the polishing surface is an area (1).

Note that the area of 70.0% or more relative to the radius R of the polishing surface from the center G of the polishing surface is an area in which the distance from the center of the polishing surface is R×70.0% or more, and the area of 99.0% or less relative to the radius R of the polishing surface from the center G of the polishing surface is an area in which the distance from the center of the polishing surface is R×99.0% or less.

The first end Eα1 and the second end Eα2 of each of the 16 grooves α are present in the area (1), and the second end Eα2 is not connected to the outer circumference of the polishing layer 1.

Hereinafter, the polishing layer provided in the polishing pad of this embodiment will be described in detail.

### <Polishing Layer>

As described above, the polishing layer provided in the polishing pad of this embodiment has one or more grooves α that each have a first end Eα1 and a second end Eα2 which is closer to the outer circumference of the polishing surface than the first end Eα1 is and that each extend from the first end Eα1 toward the second end Eα2.

### (Groove α)

In the polishing pad of this embodiment, the first end Eα1 of the groove α is present in the area (1) which is a range of 70.0 to 99.0% relative to the radius of the polishing surface from the center of the polishing surface.

When the first end Eα1 of the groove α is present in the area (1), the discharge of a slurry in the polishing area is not too high and while maintaining a good polishing rate, the fluidity of the slurry in the polishing area is enhanced, making it possible to enhance the polishing uniformity in an edge area.

The area in which the first end Eα1 of the groove α is present is not particularly limited, but is preferably a range of 70.0 to 95.0% relative to the radius of the polishing surface from the center of the polishing surface, more preferably 75.0 to 94.0%, and further preferably 80.0 to 93.0%.

When the area in which the first end Eα1 of the groove α is present is in the above range, a better polishing rate and a better polishing uniformity in an edge area tend to be easily achieved.

In the polishing pad of this embodiment, the second end Eα2 of the groove α is not connected to the outer circumference of the polishing layer.

When the second end Eα2 of the groove α is not connected to the outer circumference of the polishing layer, the discharge of a slurry of the polishing area is not too high, and while maintaining a good polishing rate, the fluidity of the slurry in the polishing area is enhanced, making it possible to enhance the polishing uniformity in an edge area.

The area in which the second end Eα2 of the groove α is present is not particularly limited, but is preferably a range of 85.0 to 99.9% relative to the radius of the polishing surface from the center of the polishing surface, more preferably 86.0 to 99.5%, and further preferably 94.0 to 99.0%.

When the area in which the second end Eα2 of the groove α is present is in the above range, a better polishing rate and a better polishing uniformity in an edge area tend to be easily achieved.

The length of the groove α is not particularly limited, but is preferably 9 to 100 mm, more preferably 20 to 80 mm, and further preferably 25 to 70 mm.

When the length of the groove α is the above lower limit or more, the supply and discharge of a slurry to the polishing area tend to be preferable so that a better polishing uniformity in an edge area is easily achieved. In addition, when the length of the groove α is the above upper limit or less, the discharge of a slurry tends to be not too high so that a better polishing rate is easily achieved.

Note that, in this Description, the “length” of a groove means a length from one end to the other end along the longest axis of the groove.

The number of the grooves α provided in the polishing layer is one or more, preferably 2 to 36, more preferably 4 to 26, and further preferably 6 to 20.

When the number of the grooves α is the above lower limit or more, the supply and discharge of a slurry to the polishing area tend to be improved so that a better polishing uniformity in an edge area is easily achieved. In addition, when the number of the grooves α is the above upper limit or less, the discharge of a slurry tends to be not too high so that a better polishing rate is easily achieved.

From the viewpoint of the polishing uniformity in an edge area, the grooves α are preferably radially formed with the radial center thereof positioned at the center of the polishing surface, and more preferably radially formed at equal intervals in the polishing surface outer circumference direction.

The shape of the groove α may be a linear shape or a curved shape. An example of the curved shape is an arc shape. In addition, the polishing layer may have both a linear groove α and a curved groove α. Among them, from the viewpoint of easily preventing liquid stagnation of a slurry in the polishing area, the groove α preferably has a linear shape.

Note that, in this Description, the shape of a groove means a shape thereof when the polishing layer is viewed in a planer view.

The sectional shape of the groove α may be, for example, a quadrilateral shape, such as rectangular, square, trapezoid, or inverted trapezoid; a triangle shape (V-shape), a semicircular shape, or a semi-elliptic shape. Among them, from the viewpoints of processability and fluidity of a slurry, a quadrilateral shape is preferred.

Note that, in this Description, the sectional shape of a groove means a shape of a cross section in the direction perpendicular to the length direction of the groove.

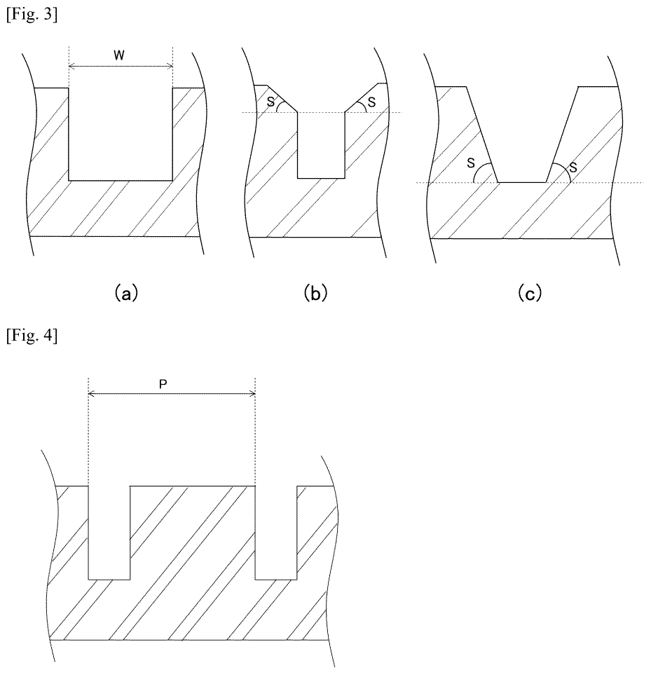

FIGS. 3(a) to (c) show schematic sectional views of grooves when each groove is cut in the direction perpendicular to the length direction thereof.

The groove α preferably has a sectional shape that has inclinations so that the groove is inversely tapered toward the opening thereof for preventing generation of burrs in polishing. Specifically, a so-called Y-shape which has a tapered portion in which two corners that form a quadrilateral groove and that are positioned in the polishing surface are chamfered so as to incline at a certain angle S as shown in FIG. 3(b) or an inverted trapezoid section that is formed so that the oblique sides incline at a certain angle S with respect to two corners that form the basic angles as shown in FIG. 3(c) is preferred. In this embodiment, the Y-shaped groove is encompassed in the concept of “quadrilateral shape”.

The inclination angle S is not particularly limited, but is preferably 20 degrees or more and less than 90 degrees, more preferably 25 to 80 degrees, and further preferably 30 to 75 degrees.

The inclination formed on the groove wall may be formed on the groove walls on both sides of the groove or may be formed only on one groove wall. When the inclination is formed on the groove walls on both sides of the groove, the inclination angles S may be the same as or different from each other. Examples of the combination of the different groove wall angles on both sides of the groove include 90°/60°, 80°/60°, 80°/50°, 70°/50°, 70°/40°, 60°/40°, and 60°/30°. When groove walls on both sides of the groove are present on the polishing pad inner circumference side and the polishing pad outer circumference side, the angle of the groove wall on the polishing pad inner circumference side may be larger than the angle of the groove wall on the outer circumference side, or the angle of the groove wall on the polishing pad inner circumference side may be smaller than the angle of the groove wall on the outer circumference side. In addition, when the groove walls on both sides of the groove are present on the rotating direction side of the polishing pad and the opposite side thereto, the angle of the groove wall on the rotating direction side may be larger than the angle of the groove wall on the opposite side thereto, or the angle of the groove wall on the rotating direction side may be smaller than the angle of the groove wall of the opposite side thereto.

When the inclination angle is in the above range, generation of burrs which are easily generated on corners of grooves in polishing is liable to be prevented so that reduction in the polishing rate, reduction in the polishing uniformity, and the like are liable to be prevented.

The groove width of the groove α is not particularly limited, but is preferably 0.1 to 10 mm, more preferably 0.13 to 5 mm, and further preferably 0.15 to 3 mm.

When the groove width of the groove α is in the above range, the balance between the areas of the grooves α and the land area tends to be improved so that a better polishing rate and a better polishing uniformity in an edge area are easily achieved.

Here, in this Description, the groove width means the width of the sectional shape in cutting the groove in the direction perpendicular to the length direction thereof, which is indicated by W in FIG. 3(a). However, the groove width is defined as follows depending on the sectional shape of the groove.

When the sectional shape is rectangular or square, the groove width is defined as the width in the polishing surface. In addition, in the case of trapezoid or inverted-trapezoid, it is defined as the average width of the bottom base. In addition, in the case where a chamfered tapered portion is formed, as in the Y-shape, it is defined as the width of the groove section in the polishing surface on assumption that the tapered portion is not formed. In addition, in the case of triangle, semicircular, semi-elliptic, it is defined as the width at ½ of the depth.

The depth of the groove α is not particularly limited, but is preferably 0.3 to 3.0 mm, more preferably 0.5 to 2.5 mm, and further preferably 0.8 to 2.0 mm.

When the depth of the groove α is the above lower limit or more, liquid stagnation of a slurry in the grooves α tends to be prevented so that a better polishing uniformity in an edge area is easily achieved. In addition, when the depth of the groove α is the above upper limit or less, the influence of abrasion of the polishing surface can be reduced and even when the use of the polishing pad is continued, a good polishing rate and a good polishing uniformity in an edge area tend to be easily maintained.

Note that, in this Description, the depth of grooves means an average value of the depths of the deepest parts of the grooves.

### (Reference Recess β)

The polishing layer preferably further has a reference recess β.

The reference recess β is preferably a spiral, annular, or latticed reference groove β1, or reference holes β2 including a plurality of holes.

In the polishing pad 10 of FIG. 1, as an aspect of the reference recess β, a spiral groove H that has substantially equal groove pitches P from the spiral center which coincides with the center G of the polishing surface of the polishing layer 1 and that has a number of spiral revolutions of 10 is formed. Note that a spiral having an equal groove pitch is also referred to as an Archimedes spiral.

From the viewpoint of spreading a slurry throughout the polishing area, the reference recess β is preferably formed from the area of 5.0% or less to the area of 90.0% or more relative to the radius of the polishing surface from the center of the polishing surface, more preferably formed from the area of 4.5% or less to the area of 95.0% or more, and further preferably formed from the area of 4.0% or less to 100.0%.

### (Reference Groove β1)

The reference groove β1 is a spiral groove, annular grooves, or a latticed groove, and among them, from the viewpoints of the polishing rate, and the polishing uniformity in an edge area, a spiral groove and annular grooves are preferred. As the annular grooves, concentric grooves are preferred.

When the reference groove β1 is a spiral groove, the position of the starting point of the spiral groove is not particularly limited, but, relative to the radius of the polishing surface from the center of the polishing surface, is preferably in the range of 5.0% or less, more preferably 4.5% or less, and further preferably 4.0% or less, and the position of the end point of the spiral groove is, relative to the radius of the polishing surface from the center of the polishing surface, preferably in the range of 90.0% or more, more preferably 95.0% or more, and further preferably, the end point reaches the outer circumference of the polishing layer.

When the reference recess β is concentric grooves, the area through which the annular groove that is nearest to the center of the polishing surface passes is not particularly limited, but, relative to the radius of the polishing surface from the center of the polishing surface, is preferably in the range of 5.0% or less, more preferably 4.5% or less, and further preferably 4.0% or less, the area through which the annular groove that is farthest to the center of the polishing surface passes is, relative to the radius of the polishing surface from the center of the polishing surface, preferably in the range of 90.0% or more, and more preferably 95.0% or more.

The sectional shape of the reference groove β1 is not particularly limited, and examples thereof include the same shapes as the sectional shape of the groove α. Among them, from the viewpoints of processability, and retention and supply stability of a slurry, a quadrilateral shape is preferred.

From the same point of view as for the grooves α, the sectional shape of the reference groove β1 is also preferably has a cross section that has inclinations so that the groove is inversely tapered toward the opening thereof. Preferred aspects of the cross section with inclinations are the same as for the groove α.

The groove width of the reference groove β1 is not particularly limited, but is preferably 0.1 to 4 mm, more preferably 0.13 to 2 mm, and further preferably 0.15 to 1 mm.

When the groove width of the reference groove β1 is within the above range, the balance between the areas of the reference groove β1 and the land area tends to be improved so that a better polishing rate and a better polishing uniformity in an edge area are easily achieved.

The depth of the reference groove β1 is not particularly limited, but is preferably 0.2 to 3.0 mm, more preferably 0.4 to 2.5 mm, and further preferably 0.8 to 2.0 mm.

When the depth of the reference groove β1 is the above upper limit or less, supply of a slurry to the polishing area and deformation resistance of the polishing pad tend to be easily improved. In addition, when the depth of the reference groove β1 is the above lower limit or more, a sufficient amount of a slurry tends to be retained in the polishing area so that a better polishing rate is easily achieved.

When the polishing layer has the reference groove β1, the depth of the groove α is not particularly limited, but is preferably 0.5 to 2.5 times the depth of the reference groove β1, more preferably 0.7 to 1.8 times, and further preferably 0.9 to 1.4 times.

When the depth of the groove α relative to the depth of the reference groove β1 is the above lower limit or more, the influence of abrasion of the polishing surface can be reduced, and even when the use of the polishing pad is continued, a good polishing rate and a good polishing uniformity in an edge area tend to be easily maintained. In addition, when the depth of the groove α relative to the depth of the reference groove β1 is the above upper limit or less, liquid stagnation of a slurry in the grooves α tends to be prevented so that a better polishing uniformity in an edge area is easily achieved.

In a spiral groove, concentric grooves, or a latticed groove as the reference groove β1, a groove pitch P which is the interval between adjacent grooves is not particularly limited, but is preferably 1 to 15 mm, more preferably 1.5 to 12 mm, and further preferably 2 to 10 mm.

When the groove pitch P is the above lower limit or more, a sufficient amount of a slurry tends to be supplied to the polishing area so that a better polishing rate is easily achieved. In addition, when the groove pitch P is the above upper limit or less, the balance between the areas of the reference groove β1 and the land area tends to be improved so that a better polishing rate and a better polishing uniformity are easily achieved.

FIG. 4 shows a schematic sectional view obtained by cutting a groove in the direction perpendicular to the length direction thereof. In this Description, the groove pitch P means the interval between adjacent grooves indicated by P in FIG. 4.

The spiral groove as the reference groove β1 may be one spiral groove or may include two or more spiral grooves in which the multiple spiral grooves are arranged in parallel. Specifically, the number of the spiral grooves arranged in parallel is preferably 1 to 16, and further preferably 1 to 10.

From the viewpoint of easily achieving a uniform fluidity of a slurry, the center of the spiral groove or concentric grooves as the reference groove β1 preferably coincides with the center of the polishing surface. On the other hand, from the viewpoint of easily preventing transcription of the groove shapes to the surface to be polished of a material to be polished caused by the phenomenon that polishing acts too much along the grooves, the spiral groove or concentric grooves may be eccentric groove(s) the center of which does not coincide with the center of the polishing surface.

It is preferred that the polishing layer has the reference groove β1 and the groove α intersects the reference groove β1 at least at one point.

In the polishing surface of the polishing layer 1 of the polishing pad 10 shown in FIG. 1, the 16 grooves α each form an intersecting portion with the spiral groove H.

When the grooves α intersect the reference groove β1, the supply and discharge of a slurry to the polishing area are improved and fluidity of the slurry in the polishing area is enhanced, making it possible to more enhance the uniformity of slurry distribution in the polishing area.

The reference holes β2 are, for example, preferably formed in a certain pattern, such as a circular, oblique, or polygonal shape, in a plan view of the polishing layer. The holes preferably each have a recessed shape which does not pass through the polishing layer.

The depth of each of the holes constituting the reference holes β2 is not particularly limited, but is less than or equal to the thickness of the polishing layer, and preferably 0.2 to 5.0 mm, more preferably 0.3 to 3.0 mm, and further preferably 0.4 to 2.5 mm.

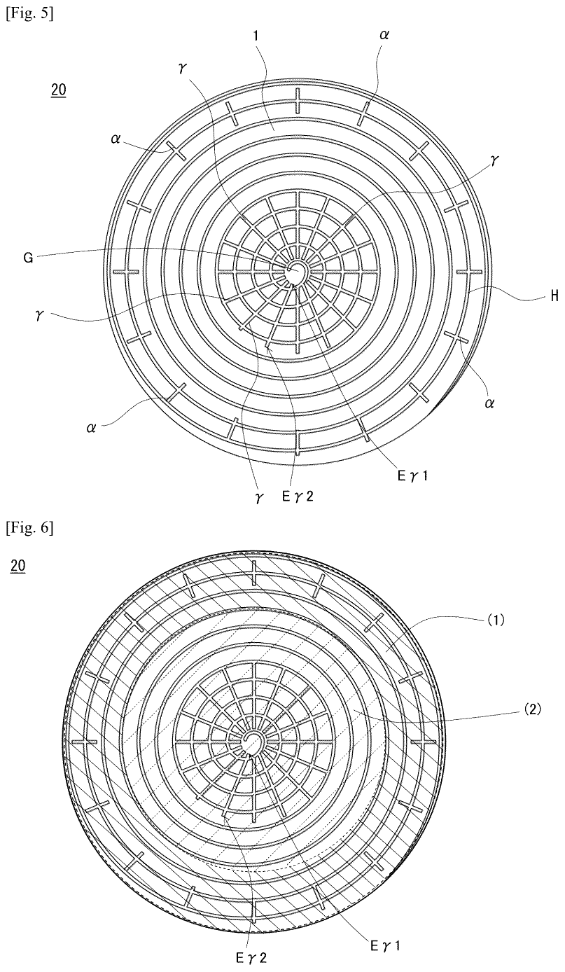

FIG. 5 is a schematic plan view for explaining a polishing pad 20 which is an example of the polishing pad of this embodiment.

The polishing layer 1 provided in the polishing pad 20 has the same grooves α and spiral groove H as those provided in the polishing pad 10 in FIG. 1, and further has 16 grooves γ that each have a first end Eγ1 and a second end Eγ2 which is closer to the outer circumference of the polishing surface than the first end Eγ1 is and that each extend from the first end Eγ1 toward the second end Eγ2.

The 16 grooves γ each have a linear shape and are radially formed at equal intervals in the polishing surface outer circumference direction with the radial center thereof positioned at the center G of the polishing surface, and each of the grooves γ and one of the grooves α are formed on the same straight line that connects the center G of the polishing surface and the outer circumference of the polishing surface.

FIG. 6 shows an explanatory drawing for explaining areas in the polishing surface of the polishing pad 20.

In the polishing pad 20, the hatched circular area indicated with solid lines which is a range of 70.0 to 99.0% relative to the radius from the center G of the polishing surface is an area (1), and the hatched area indicated with dotted lines which is a range of less than 70.0% relative to the radius of from the center G of the circular polishing surface is an area (2).

The first end Eγ1 and the second end Eγ2 of each of the 16 grooves γ are present in the area (2).

### (Groove γ)

In the polishing pad of this embodiment, the first end Eγ1 of the groove γ is present in the area (2) which is a range of less than 70.0% relative to the radius of the polishing surface from the center of the polishing surface.

When the first end Eγ1 of the groove γ is present in the area (2), a sufficient amount of a slurry tends to be supplied to the polishing area so that a better polishing rate is easily achieved.

The area in which the first end Eγ1 of the groove γ is present is not particularly limited, but is preferably in the range of 0.0 to 20.0%, more preferably 2.0 to 15.0%, and further preferably 3.0 to 10.0% relative to the radius of the polishing surface from the center of the polishing surface.

When the area in which the first end Eγ1 of the groove γ is present is in the above range, a slurry dropwise added to the polishing surface tends to enter the groove γ at an appropriate timing so that the slurry is easily uniformly distributed to the polishing area.

Note that, when the number of the grooves γ provided in the polishing layer is two or more, the first end Eγ1 of the groove γ means the end of the groove γ that is closest to the center of the polishing surface.

In addition, the phrase “the area in which the first end Eγ1 is present is 0% relative to the radius of the polishing surface from the center of the polishing surface” means that the position of the first end Eγ1 is at the center of the polishing surface. In addition, in this embodiment, when the position of the first end Eγ1 is 0% relative to the radius of the polishing surface from the center of the polishing surface, the grooves γ may be connected at the center of the polishing surface in some cases. In this case, the connected grooves γ are not counted collectively as one groove but counted as the number corresponding to the number of the second ends.

The area in which the second end Eγ2 of the groove γ is present is not particularly limited, but, relative to the radius of the polishing surface from the center of the polishing surface, is preferably in the range of 30.0 to 80.0%, more preferably 40.0 to 75.0%, and further preferably 45.0 to 70.0%.

When the second end Eγ2 of the groove γ is present in this area, a slurry that enters the groove γ tends to be appropriately delivered to the polishing area and the discharge of a slurry tends to be not too high so that a better polishing rate is easily achieved.

Note that, when the number of the grooves γ provided in the polishing layer is two or more, the second end Eγ2 of the groove γ means the end of the groove γ that is farthest from the center of the polishing surface.

The first end Eα1 of the groove α is preferably closer to the outer circumference of the polishing surface than the second end Eγ2 of the groove γ is. Because of this configuration, the discharge of a slurry in the polishing area tends to be not too high so that the polishing uniformity in an edge area is easily enhanced while maintaining a good polishing rate.

From the same point of view, the difference between the distance A from the center of the polishing surface to the first end Eα1 of the groove α and the distance B from the center of the polishing surface to the second end Eγ2 of the groove γ [distance A-distance B] is not particularly limited, but, relative to the radius of the polishing surface, is preferably 8.0 to 50.0%, more preferably 10.0 to 45.0%, and further preferably 15.0 to 40.0%.

The number of the grooves γ provided in the polishing layer is not particularly limited, but preferably one or more, more preferably 2 to 36, further preferably 4 to 26, and furthermore preferably 6 to 20.

When the number of the grooves γ is in the above range, the slurry retention of the polishing area tends to be enhanced since the balance between supply and discharge of a slurry is superior.

The number of the grooves α provided in the polishing layer may be the same as or may be different from the number of the grooves γ.

The shape of the groove γ may be a linear shape or may be a curved shape. In addition, the polishing layer may have both a groove γ having a linear shape and a groove γ having a curved shape. Among them, from the viewpoint of easily preventing liquid stagnation of a slurry in the polishing area, the groove γ preferably has a linear shape.

When the polishing pad of this embodiment has the groove α and the groove γ, at least one of the groove α and the groove γ preferably has a linear shape.

From the viewpoint of the polishing uniformity in an edge area, the grooves γ are preferably radially formed with the radial center positioned at the center of the polishing surface, and more preferably radially formed at equal intervals in the polishing surface outer circumference direction.

When the grooves γ and the grooves α are radially formed with the radial center thereof positioned at the center of the polishing surface, each of the grooves γ and one of the grooves α may be formed on the same straight line that connects the center of the polishing surface and the outer circumference of the polishing surface or may be formed on different straight lines, but from the viewpoint of easiness of processing of the grooves, are preferably formed on the same straight line.

The sectional shape of the groove γ is not particularly limited, and examples thereof include the same shapes as the sectional shape of the groove α. Among them, from the viewpoints of processability, and retention and supply stability of a slurry, a quadrilateral shape is preferred.

From the same point of view as for the groove α, the sectional shape of the groove γ is also preferably a cross section that has inclinations so that the groove is inversely tapered toward the opening thereof. Preferred aspects of the cross section with inclinations are the same as for the groove α.

The groove width of the groove γ is not particularly limited, but is preferably 0.1 to 10 mm, more preferably 0.13 to 5 mm, and further preferably 0.15 to 3 mm.

When the groove width of the groove γ is in the above range, the balance between the areas of the grooves γ and the land area tends to be improved so that a better polishing rate and a better polishing uniformity are easily achieved.

The depth of the groove γ is not particularly limited, but is preferably 0.2 to 3.0 mm, more preferably 0.4 to 2.5 mm, and further preferably 0.8 to 2.0 mm.

When the depth of the groove γ is the above upper limit or less, supply of a slurry to the polishing area and deformation resistance of the polishing pad tend to be better. In addition, when the depth of the groove γ is the above lower limit or more, a sufficient amount of a slurry tends to be retained in the polishing area so that a better polishing rate is easily achieved.

The depth of the groove γ may be constant or may change in the middle of the groove.

The point at which the depth of the groove γ changes may be, for example, in an area of 2 to 50% relative to the length of the groove γ from the first end Eγ1.

When the depth of the groove γ becomes shallower from the second end Eγ2 toward the first end Eγ1, the processing accuracy tends to be enhanced.

When the polishing layer provided in the polishing pad of this embodiment has the reference groove β1 and the groove γ, the reference groove β1 and the groove γ preferably intersect at least at one point.

When the groove γ intersects the reference groove β1, a slurry that enters the groove γ is easily rapidly supplied and retained in the polishing area.

In the polishing surface of the polishing layer 1 of the polishing pad 20 shown in FIG. 5, the 16 grooves γ each form an intersecting portion with the spiral groove H.

The length of the groove γ is not particularly limited, but is preferably 100 to 280 mm, more preferably 120 to 250 mm, and further preferably 150 to 230 mm.

When the length of the groove γ is the above lower limit or more, supply of a slurry to the polishing area tends to be better. In addition, when the length of the groove γ is the above upper limit or less, discharge of a slurry tends to be not too high so that a better polishing rate is easily achieved.

The length of the groove α is not particularly limited, but is preferably 5.0 to 100.0% relative to the length of the groove γ, more preferably 8.0 to 70.0%, and further preferably 10.0 to 65.0%.

When the relation between the lengths of the groove α and the groove γ is in the above range, the polishing uniformity in an edge area tends to be easily enhanced while maintaining the polishing rate.

### (Shape and the Like of Polishing Layer)

As the diameter of the circular polishing surface, a diameter of the polishing surface of a typical circular polishing pad used in CMP can be adopted. For example, the diameter of the circular polishing surface is preferably 500 to 780 mm. Thus, the radius of the circular polishing surface is preferably, for example, 250 to 390 mm.

The thickness of the polishing layer is not particularly limited, but is preferably 0.4 to 5 mm, more preferably 0.6 to 4.5 mm, and further preferably 1.2 to 2.5 mm.

When the thickness of the polishing layer is in the above range, stability of the polishing performance tends to be enhanced while enhancing productivity and handling.

The polishing layer preferably has a non-foaming structure (non-porosity). The polishing layer that has a non-forming structure (non-porosity) can maintain a high hardness, shows a more superior flattening property, and is less liable to generate scratches since abrasive grains in a slurry do not aggregate or agglutinate in the pores. In addition, as compared with a polishing layer of a foaming structure, since the abrasion rate of the polishing layer is smaller, the life of the polishing pad can be prolonged.

### (Hardness of Polishing Layer)

The D hardness of the polishing layer is not particularly limited, but is preferably 45 to 90, more preferably 50 to 88, further preferably 55 to 87, and furthermore preferably 60 to 86.

When the D hardness of the polishing layer is in the above range, polishing uniformity tends to be able to more enhanced.

The D hardness can be measured according to JIS K 7311:1995, and more specifically, can be measured by a method described in the section of Examples.

### (Density of Polishing Layer)

The density of the polishing layer is not particularly limited, but is preferably 1.0 g/cm³ or more, more preferably 1.1 g/cm³ or more, and further preferably 1.2 g/cm³ or more. When the density of the polishing layer is the above lower limit or more, a better polishing rate and a better polishing uniformity tend to be easily achieved.

The upper limit of the density of the polishing layer is not particularly limited, but from the viewpoints of easiness of production and the like, may be 1.4 g/cm³ or less, and may be 1.3 g/cm³ or less.

The density of the polishing layer can be determined as a weight (g) relative to the outside dimension (cm³).

Next, the material for forming and the method for producing the polishing layer provided in the polishing pad of this embodiment will be described.

### <Material for Forming Polishing Layer>

As a material for forming the polishing layer, a synthetic or natural polymer material that has conventionally been used for producing a polishing layer of a polishing pad can be used.

Examples of the polymer material include a polyurethane, a polyethylene, a polypropylene, a polybutadiene, an ethylene-vinyl acetate copolymer, a butyral resin, a polystyrene, a polyvinyl chloride, an acrylic resin, an epoxy resin, a polyester, and a polyamide. One of them may be used alone or two or more thereof may be used in combination.

Among them, from the viewpoint of being superior in flatness and easily providing a polishing layer in which a scratch is hardly generated, a polyurethane is preferred.

The polyurethane which is used as a material for forming the polishing layer will be described in detail below as a representative example.

A polyurethane is obtained by reacting polyurethane raw materials containing a polymer diol, an organic diisocyanate, and a chain extender.

Specific examples of the polymer diol include polyether diols, such as polyethylene glycol and polytetramethylene glycol; polyester diols, such as poly(nonamethylene adipate)diol, poly(2-methyl-1,8-octamethylene adipate)diol, and poly(3-methyl-1,5-pentamethylene adipate)diol; and polycarbonate diols, such as poly(hexamethylene carbonate)diol and poly(3-methyl-1,5-pentamethylene carbonate)diol. One of them may be used alone or two or more thereof may be used in combination. Among them, a polyether diol is preferred, and polytetramethylene glycol is more preferred.

Specific examples of the organic diisocyanate include aliphatic or alicyclic diisocyanates, such as hexamethylene diisocyanate, isophorone diisocyanate, 4,4′-dicyclohexylmethane diisocyanate, and 1,4-bis(isocyanatomethyl)cyclohexane; and aromatic diisocyanates, such as 4,4′-diphenylmethane diisocyanate, 2,4-tolylene diisocyanate, 2,6-tolylene diisocyanate, and 1,5-naphthylene diisocyanate. One of them may be used alone or two or more thereof may be used in combination. Among them, from the viewpoint of being superior in abrasion resistance of the polishing layer, an aromatic diisocyanate is preferred, and 4,4′-diphenylmethane diisocyanate is more preferred.

An example of the chain extender is a low molecular weight compound that has a molecular weight of 350 or less and has, in the molecular, 2 or more active hydrogen atoms which can react with an isocyanate group.

Specific examples of the chain extender include diols, such as ethylene glycol, diethylene glycol, 1,3-propanediol, 1,2-butanediol, 1,3-butanediol, 1,4-butanediol, 1,5-pentanediol, neopentyl glycol, 1,6-hexanediol, 3-methyl-1,5-pentanediol, 1,4-bis(p-hydroxyethoxy)benzene, 1,9-nonanediol, cis-2-butene-1,4-diol, and spiroglycol; and diamines, such as ethylenediamine, tetramethylenediamine, hexamethylenediamine, nonamethylenediamine, hydrazine, xylylenediamine, isophoronediamine, and piperazine. One of them may be used alone or two or more thereof may be used in combination. Among them, at least one selected from 1,4-butanediol, cis-2-butene-1,4-diol, 1,5-pentanediol, and 1,9-nonanediol is preferred.

The blending ratio of the polyurethane raw material components is appropriately adjusted in view of the characteristics to be imparted to the polishing layer, and, for example, the amount of isocyanate groups contained in the organic diisocyanate blended relative to 1 mole of active hydrogen atom contained in the polymer diol and the chain extender is preferably 0.95 to 1.3 moles, more preferably 0.96 to 1.1 moles, and further preferably 0.97 to 1.05 moles.

When the blending ratio is the above lower limit or more, mechanical strength and abrasion resistance of the polyurethane tend to be enhanced. In addition, when the blending ratio is the above upper limit or less, productivity and storage stability of the polyurethane tend to be easily enhanced.

From the viewpoint of obtaining a polishing layer having a high hardness and a superior flatness, the polyurethane is preferably a thermoplastic polyurethane. Note that thermoplastic means a property capable of being molten and molded by a heating step in extrusion, injection molding, calender molding, 3D printer molding, or the like.

A thermoplastic polyurethane is obtained, for example, by polymerization by a urethanization reaction in which the polyurethane raw materials are used and a known prepolymer method or a one-shot method is used. More specifically, the method for producing a thermoplastic polyurethane is preferably a production method by performing melt polymerization while melt-mixing polyurethane raw materials substantially in the absence of a solvent, and from the viewpoint of productivity, is more preferably a production method by performing a continuous melt polymerization while melt-mixing polyurethane raw materials using a multi-screw extruder.

### <Method for Producing Polishing Layer>

The polishing layer can be produced, for example, by a method in which additives and the like for a polishing layer are blended according to the need to the aforementioned polymer material, and the resulting polymer material composition is formed into a sheet.

The content of the polymer material in the polymer material composition is not particularly limited, but is preferably 50% by mass or more, more preferably 80% by mass or more, further preferably 90% by mass or more, and furthermore preferably 99% by mass or more.

An example of a method for forming the polymer material composition into a sheet is a method in which the polymer material composition is melt-extruded into a sheet with an extruder, such as a single screw extruder or a twin screw extruder, having a T-die mounted thereon. Alternatively, the polymer material composition may be molded into a block shape and the block-shaped molded body may be sliced into a sheet.

The thickness of the polymer material composition sheet formed by such a method as described above is adjusted into a desired thickness by grinding or the like, and is subjected to cutting, punching, grinding, or the like to be molded into a desired shape, thereby obtaining a sheet for a polishing layer. Then, one surface of the sheet for a polishing layer is set as the polishing surface and the various grooves as described above are provided on the polishing surface, thereby obtaining a polishing layer to be used in the polishing pad of this embodiment.

Examples of a method of forming a groove include a method in which, one surface of the sheet for a polishing layer is subjected to cutting processing to form a groove; a method in which transfer processing in which a heated mold, metal wire, or the like is brought into contact with one surface of the sheet for a polishing layer by stamping is performed to melt or volatilize a polymer, thereby forming a groove; a method in which one surface of the sheet for a polishing layer is subjected to laser processing to decompose or volatilize a polymer, thereby forming a groove; and a method in which a mold having previously formed a projection for forming a groove is used to mold a sheet for a polishing layer having a polishing surface with a groove. Among them, from the viewpoint of a superior productivity, a method of cutting processing or a method of transfer processing is preferred, and from the viewpoint of a superior processing accuracy, a method of cutting processing is more preferred.

The polishing layer produced as described above may be used as it is as a single layer polishing pad or may be used as a polishing pad that has a laminate structure having two or more layers in which another layer, such as a cushion layer or a support layer, is laminated on the opposite surface to the polishing surface of the polishing layer.

When the polishing pad has a laminate structure, a cushion layer, a support layer, or the like is laminated via a pressure-sensitive adhesive, another adhesive, or the like on the opposite surface to the polishing surface of the polishing layer.

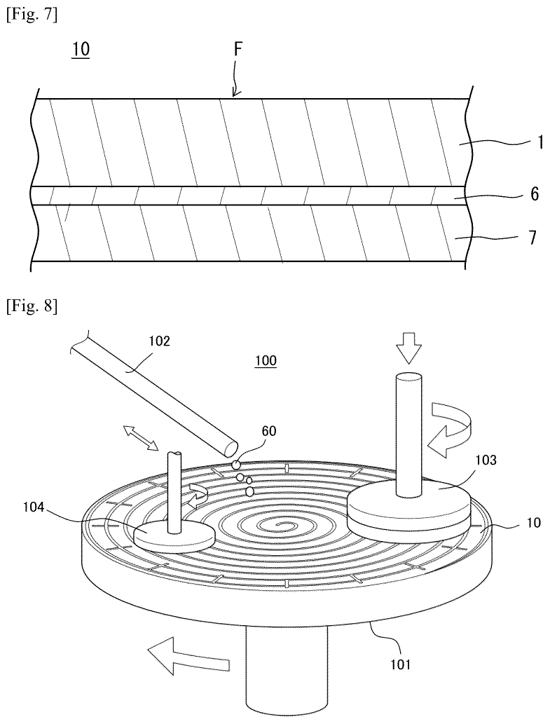

FIG. 7 is a schematic sectional view of a part of a cross section in the thickness direction for explaining the layer structure of the polishing pad 10.

The polishing pad 10 has a laminate structure in which a cushion layer 7 is bonded to the opposite surface to the polishing surface F of the polishing layer 1 via an adhesive layer 6.

### <Cushion Layer>

From the viewpoint of enhancing polishing uniformity throughout the entire surface, the polishing pad may have a cushion layer.

The cushion layer is preferably a layer having a lower hardness than the hardness of the polishing layer. When the hardness of the cushion layer is lower than the hardness of the polishing layer, a hard polishing layer follows a topical unevenness of the surface to be polished and the cushion layer follows a warp or waviness of the entire material to be polished so that it Is possible to achieve polishing superior in the balance between global flatness (a state with reduced unevenness of a large period on a wafer substrate) and local flatness (state with reduced topical unevenness).

Examples of a material used as the cushion layer include a composite in which a nonwoven fabric is impregnated with a polyurethane (for example, “Suba 400” (manufactured by Nitta Haas Incorporated)); rubbers, such as natural rubber, nitrile rubber, polybutadiene rubber, and silicone rubber; thermoplastic elastomers, such as a polyester-based thermoplastic elastomer, a polyamide-based thermoplastic elastomer, and a fluorine-based thermoplastic elastomer; an expanded plastic; and a polyurethane.

Among them, from the viewpoint of easily achieving a preferable softness for a cushion layer, a polyurethane having a foam structure is preferred.

The thickness of the cushion layer is not particularly limited, but is preferably 0.5 to 5 mm. When the thickness of the cushion layer is the above lower limit or more, a sufficient following effect to a warp or waviness of the entire surface to be polished tends to be obtained, leading to a better global flatness. In addition, when the thickness of the cushion layer is the above upper limit or less, the entire polishing pad tends to have an appropriate hardness, leading to a better polishing stability.

When the polishing pad of this embodiment has no cushion layer, a suitable thickness of the polishing pad of this embodiment is the same as the suitable thickness of polishing layer described above. In addition, when the polishing pad of this embodiment has a cushion layer, the thickness of the polishing pad of this embodiment is preferably 1 to 10 mm.

### [Polishing Method]

The polishing method of this embodiment is a polishing method including polishing a material to be polished by using the polishing pad of this embodiment in which the grooves α are disposed under a retainer ring that surrounds the material to be polished.

An embodiment in the case where CMP is performed using the polishing pad of this embodiment will be described.

FIG. 8 shows a schematic view of a CMP apparatus 100.

The CMP apparatus 100 includes a circular rotary fixed plate 101, a slurry supply nozzle 102, a polishing head 103 that holds a material to be polished, and a pad conditioner 104, and the polishing pad 10 is bonded on a surface of the rotary fixed plate 101 with a double-sided pressure-sensitive adhesive sheet or the like.

In the CMP apparatus 100, the rotary fixed plate 101 rotates, for example, in the direction indicated by the arrow (clockwise direction) by a motor not shown. In addition, the polishing head 103 rotates, for example, in the direction indicated by the arrow (clockwise direction) by a motor not shown while bringing a surface to be polished of a material to be polished 50 into pressure-contact with the polishing surface of the polishing pad 10.

The pad conditioner 104 rotates, for example, in the direction indicated by the arrow (clockwise direction). When the diameter of the pad conditioner 104 is smaller than the diameter of the material to be polished 50, the pad conditioner 104 is allowed to swing in the radius direction of the rotary fixed plate 101 in order to allow the entire area that is to be in contact with the material to be polished, of the polishing pad to have a roughness suitable for polishing.

When an unused polishing pad is used, in general, prior to polishing a material to be polished, conditioning referred to as brake-in is performed for forming a roughness suitable for polishing by finely roughening the polishing surface of the polishing pad. Specifically, the pad conditioner 104 for CMP is pressed on the surface of the polishing pad 10 that is rotating in the state fixed to the rotary fixed plate 101 while watering the surface, thereby performing conditioning of the surface of the polishing pad 10. As the pad conditioner, for example, a pad conditioner in which diamond particles are fixed on a carrier surface by nickel electrodeposition or the like is used.

In the polishing method of this embodiment, the grooves α that the polishing pad of this embodiment has are disposed under the retainer ring. According to this configuration, the supply and discharge of a slurry inside the retainer ring are improved to enhance the uniformity of distribution of the slurry in the polishing area, resulting in a better polishing uniformity in an edge area.

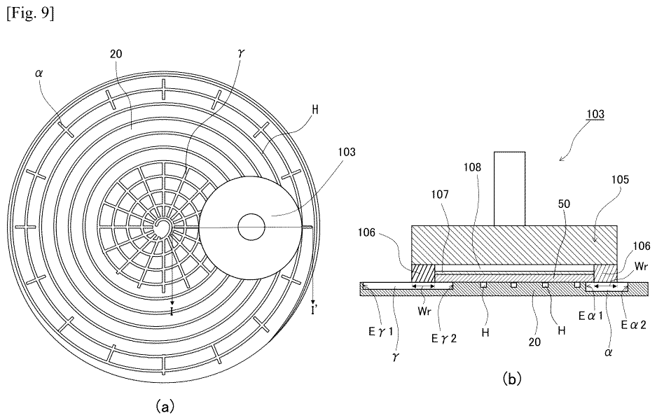

FIG. 9(a) shows a schematic plan view of the polishing pad 20 and the polishing head 103, and FIG. 9(b) shows a schematic sectional view in the I-I′ cross section of FIG. 9(a).

As shown in FIG. 9(b), the polishing head 103 is, for example, composed of a head main body 105, a retainer ring 106 that surrounds the outer circumference of the material to be polished 50, an elastic membrane 107 that presses the top surface of the material to be polished 50, an air chamber 108 surrounded by the elastic membrane 107, the retainer ring 106, and the head main body 105, and the like.

The retainer ring 106 plays a role of surrounding the outer circumference of the material to be polished 50 to prevent the material to be polished 50 from running out while pressing the polishing surface of the polishing pad 20 to flatten the polishing surface of the polishing pad 20 that is polishing the material to be polished 50.

As shown in FIG. 9(b), the first end Eα1 of the groove α disposed under the retainer ring 106 is present in an area inside the retainer ring 106 and the second end Eα2 of the groove α is present in an area outside the retainer ring 106.

When the groove α and the retainer ring have the above positional relation, the supply and discharge of a slurry inside the retainer ring tends to be improved, leading to a better polishing uniformity in an edge area.

From the viewpoint of achieving the above positional relation between the groove α and the retainer ring, the length of the groove α is preferably longer than a width Wr (distance in the radial direction between the inner circumference and the outer circumference) of the retainer ring 106.

In addition, as shown in the schematic sectional view of FIG. 9(b), when the polishing layer has the groove γ, the groove γ is preferably disposed under the retainer ring 106, and it is more preferred that the first end Eγ1 of the groove γ disposed under the retainer ring 106 is present in an area outside the retainer ring 106 and the second end Eγ2 of the groove γ is present in an area inside the retainer ring.

When the groove γ and the retainer ring have the above positional relation, the supply and discharge of a slurry inside the retainer ring tends to be improved, leading to a better polishing uniformity in an edge area.

From the viewpoint of achieving the above positional relation between the groove γ and the retainer ring, the length of the grooves γ is preferably longer than the width Wr (distance in the radial direction between the inner circumference and the outer circumference) of the retainer ring 106.

After completing the brake-in, polishing of the surface to be polished of the material to be polished is started. In the polishing, a slurry is supplied from a slurry supply nozzle to the surface of the rotating polishing pad.

The slurry contains, for example, a liquid medium, such as water or an oil; an abrasive, such as silica, alumina, cerium oxide, zirconium oxide, or silicon carbide; and a base, an acid, a surfactant, an oxidant, a reductant, a chelating agent, and the like. In addition, in performing CMP, in addition to a slurry, a lubricating oil, a cooling agent, or the like may be used together, according to the need.

Then, onto the polishing pad in which the slurry is uniformly spread throughout the polishing surface of the polishing layer, an object to be polished that is rotating in the state fixed to the polishing head is pressed. Then, a polishing treatment is continued until a prescribed flatness is obtained. By controlling the pressing force exerted in polishing and the rate of the relative motion of the rotary fixed plate and the holder, the finishing quality is influenced.

The conditions in polishing are not particularly limited, but for efficiently performing polishing, the rotation speeds of the rotary fixed plate and the holder are each preferably as low as 300 rpm or less, and the pressure exerted to the object to be polished is preferably 150 kPa or less so that a flaw does not appear after polishing. During polishing, a slurry is preferably continuously supplied onto the polishing surface with a pomp or the like. The amount of the slurry supplied is not particularly limited, but is preferably such an amount that the polishing surface is always covered with the slurry.

Then, the object to be polished after completion of the polishing is washed well with running water, and then, the water drops deposited on the object to be polished are preferably eliminated and dried with a spin dryer or the like. By polishing the surface to be polished with a slurry in this manner, it is possible to attain a smooth surface throughout the surface to be polished. Note that the CMP as described above can be suitably used for polishing, for example, various semiconductor materials, such as a silicon wafer.

The polishing method of this embodiment is preferably used for polishing in a process for producing various semiconductor devices, MEMS (micro-electro-mechanical systems), and the like.

Examples of the material to be polished include semiconductor base materials, such as silicon, silicon carbide, gallium nitride, gallium arsenide, zinc oxide, sapphire, germanium, and diamond; insulating films, such as a silicon oxide film, a silicon nitride film, and a low-k film, or wiring materials, such as copper, aluminum, and tungsten which are formed on semiconductor base materials; glass, rock crystal, an optical base material, and a hard disc. Among them, the polishing pad of this embodiment is preferably used for an application of polishing an insulating film, a wiring material, or the like formed on a semiconductor base material.

### [Method for Producing Semiconductor]

The method for producing a semiconductor of this embodiment is a method for producing a semiconductor, including polishing a semiconductor material by the polishing method of this embodiment.

Description of the polishing method of this embodiment is as described above.

In the method for producing a semiconductor of this embodiment, examples of a semiconductor material to be polished by the polishing method of this embodiment include such semiconductor base materials and insulating films, wiring materials, or the like formed on semiconductor base materials as described above in the section of “Polishing method of this embodiment”.

A semiconductor material polished by the polishing method of this embodiment is then washed and can be processed into a semiconductor by a known semiconductor production process.

### EXAMPLES

The present invention will be described more specifically below with reference to examples. Note that the scope of the present invention is not to be limited to these examples.

### Production Example 1

A polytetramethylene glycol [abbreviation: PTMG] having a number average molecular weight of 850, a polyethylene glycol [abbreviation: PEG] having a number average molecular weight of 600, 1,4-butanediol [abbreviation: BD], and 4,4′-diphenylmethane diisocyanate [abbreviation: MDI] were blended in a mass ratio of PTMG:PEG:BD:MDI of 24.6:11.6:13.8:50.0, and were continuously supplied to a twin screw extruder that coaxially rotates with a metering pump to conduct continuous melt-polymerization into a thermoplastic polyurethane. Then, the melt product of the polymerized thermoplastic polyurethane was continuously extruded in a strand form into water, which was then cut with a pelletizer to obtain pellets. The pellets were dehumidified and dried at 70° C. for 20 hours, and then, were supplied into a single screw extruder and were extruded from a T-die to mold a sheet. Then, a surface of the resulting sheet was grinded into a uniform sheet having a thickness of 2.0 mm, followed by cutting into a circle with a diameter of 740 mm, to obtain a sheet for a polishing layer which is a non-foaming body. The D hardness of the sheet for a polishing layer measured according to JIS K 7311:1995 was 62 under a condition of a measurement temperature of 25° C.

### [Production of Polishing Pad]

### Examples 1 to 20, Comparative Examples 1 to 4

In a polishing surface which is a surface of the sheet for a polishing layer obtained in Production Example 1, grooves having a pattern of the shape shown in Table 1 were formed by cutting processing.

In Examples 1 to 6 and 9 to 20 and Comparative Examples 1 to 4, the positions of the ends of all the grooves γ were each the position of the first end Eγ1 and the position of the second end Eγ2 shown in Table 1.

In Example 7, the position of the first end of one groove γ of the 8 grooves γ was 0%, the positions of the first ends of the ends of 7 grooves γ thereof were 5.2%, and the positions of the second ends of all the 8 grooves γ were 51.6%.

In Example 8, there were 8 grooves γ in which grooves γ each having a position of the first end of 0% and grooves γ each having a position of the first end of 5.2% were alternately arranged and the positions of the second ends of all the 8 grooves were 51.6%.

Note that, in Examples 1 to 20 and Comparative Examples 1 to 4, the grooves α were and the grooves γ were radially formed with the radial center thereof positioned at the center of the polishing surface at equal intervals in the polishing surface outer circumference direction.

When the grooves γ and the grooves α had a linear shape, each of the grooves γ and one of the grooves α were formed on the same straight line that connected the center of the polishing surface and the outer circumference of the polishing surface.

In addition, each of the grooves γ and one of the grooves α that had an arc shape were formed on the same arc that connected the center of the polishing surface and the outer circumference of the polishing surface.

Subsequently, onto the opposite surface to the polishing surface of the polishing layer, a cushion layer was bonded with a double-sided pressure-sensitive adhesive sheet to produce a double-layered polishing pad. As the cushion layer, “PORON H48” manufactured by INOAC CORPORATION which is an expanded polyurethane sheet having a thickness of 0.8 mm was used.

The groove widths of the grooves formed in the examples were measured based on a scanning electron microscope (SEM) image at a magnification of 200× of a cross section. Specifically, a cross section of each groove of a polishing layer was photographed at evenly selected 18 points, and the widths of the groove in the images were measured, and the average thereof was determined. In addition, the groove pitch P of the reference groove β1 was determined as follows: the pitches were measured with a scale loupe at 8 points evenly selected from the area that was to be in contact with a silicon wafer of the polishing surface and the average thereof was taken as the groove pitch P. In addition, the depth of each groove was determined as follows: the depths were measured with a depth gage “E-DP2J” manufactured by NAKAMURA Mfg. Co., Ltd. Corporation at 8 points evenly selected from the area that was to be in contact with a silicon wafer, and the average of the measurement values were taken as the depth of the groove.

### [Evaluation]

The polishing pad obtained in each example was evaluated for the polishing characteristics by the following evaluation methods.

### (Evaluation Method of Polishing Rate)

The polishing pad obtained in each example was mounted on a polishing apparatus “FREX-300” manufactured by EBARA CORPORATION. Then, a slurry “HS-8005” manufactured by Resonac Corporation was diluted 10 times to adjust a slurry, and while supplying the slurry onto the polishing surface of the polishing pad at a rate of 200 mL/minutes under conditions of a platen rotation number of 100 rpm, a head rotation number of 99 rpm, and a polishing pressure of 30.0 kPa, a silicon wafer with a diameter of 12 inches that had a silicon oxide film having a thickness of 2,000 nm on the surface thereof was polished for 60 seconds.

Note that, when a polishing pad having the grooves α was used, polishing was performed in a state where the grooves α were under a retainer ring mounted on the polishing head so that the end on the center side (first end Eα1) of the grooves α was present in an area inside the retainer ring and the end on the outer circumference side (second end Eα2) of the grooves α was present in an area outside the retainer ring.

In the same manner, when a polishing pad having the grooves γ was used, polishing was performed in a state where the grooves γ were under a retainer ring mounted on the polishing head so that the end on the center side (first end Eγ1) of the grooves γ was present in an area outside the retainer ring and the end on the outer circumference side (second end Eγ2) of the grooves γ was present in an area inside the retainer ring.

Then, using a pad conditioner (a diamond dresser (diamond grid number: #100 Blocky, base metal diameter: 19 cm) manufactured by A.L.M.T. Corp.), the surface of the polishing pad was conditioned for 30 seconds under conditions of a dresser rotation number or 70 rpm, a polishing pad rotation number of 100 rpm, and a dresser load of 20 N while allowing pure water to flow at a rate of 150 mL/min. Then, another silicon wafer was polished again, followed by further conditioning for 30 seconds. Then, after polishing for 60 seconds, conditioning of the polishing pad was performed for 30 seconds. Then, another silicon wafer was polished again, followed by further conditioning for 30 seconds. In this manner, 10 silicon wafers were polished.

The thicknesses of the silicon oxide film before and after polishing of the silicon wafer subjected to the tenth polishing were measured at 49 points within the wafer surface, and the polishing rate (nm/min) at each point was determined. Specifically, the average of the polishing rates at the 49 points was taken as the polishing rate.

### (Evaluation Method of Polishing Uniformity)

Under the conditions described above in the “Evaluation method of polishing rate”, the thicknesses of the silicon oxide film before and after polishing of the silicon wafer that was polished when the groove depth of the grooves α (however, when not having the groove α and having the reference groove β1, the reference groove β1) of the polishing layer was reduced 50% were measured at 87 points in the wafer surface (edge exclusion 3 mm) to determine the polishing rate (nm/min) at each point. Then, the average and the standard deviation 1σ of the polishing rates at the 87 points were calculated, and the coefficient of variation (unit: %) was determined from the average and the standard deviation 1σ. A smaller coefficient of variation indicates a more superior polishing uniformity.

### (Evaluation Method of Polishing Uniformity of Edge Area)

Under the conditions described above in the “Evaluation method of polishing rate”, the thicknesses of the silicon oxide film before and after polishing of the silicon wafer that was polished when the groove depth of the grooves α (however, when not having the groove α and having the reference groove β1, the reference groove β1) of the polishing layer was reduced 50% were measured at 20 points in an edge area of 10 mm from the outside of the wafer to determine the polishing rate (nm/min) of each point. Then, the average and the standard deviation 1σ of the polishing rates at the 20 points were calculated, and the coefficient of variation (unit: %) was determined from the average and the standard deviation 1σ. A smaller coefficient of variation indicates a more superior polishing uniformity in the edge area.

TABLE 1

| | | Example | | | | | | | | | |
|---|---|---|---|---|---|---|---|---|---|---|---|
| | | 1 | 2 | 3 | 4 | 5 | 6 | 7 | 8 | 9 | 10 |
| Grooves α | Position of first end | 83.0 | 86.0 | 86.0 | 86.0 | 86.0 | 86.0 | 86.0 | 86.0 | 80.0 | 90.0 |
| | Eα1 (%)*1 | | | | | | | | | | |
| | Position of second end | 95.0 | 96.0 | 96.0 | 96.0 | 96.0 | 96.0 | 96.0 | 96.0 | 90.0 | 99.0 |
| | Eα2 (%)*1 | | | | | | | | | | |
| | Shape | straight | straight | straight | straight | straight | straight | straight | straight | arc | straight |
| | | line | line | line | line | line | line | line | line | | line |
| | Sectional shape | rectan- | Y-shape | Y-shape | Y-shape | Y-shape | Y-shape | Y-shape | Y-shape | rectan- | Y-shape |
| | | gular | | | | | | | | gular | |
| | Groove width (mm) | 0.5 | 0.2 | 0.2 | 0.2 | 0.2 | 0.2 | 0.2 | 0.2 | 0.5 | 0.2 |
| | Depth (mm) | 1.5 | 1.5 | 1.3 | 1.5 | 1.5 | 1.3 | 1.3 | 1.3 | 1.6 | 1.6 |
| | Number | 16 | 8 | 8 | 8 | 8 | 8 | 8 | 8 | 16 | 8 |
| | Presence or absence of | pres- | pres- | pres- | pres- | pres- | pres- | pres- | pres- | pres- | pres- |
| | intersection with | ence | ence | ence | ence | ence | ence | ence | ence | ence | ence |
| | reference groove β1 | | | | | | | | | | |
| Reference | Shape | concentric | spiral | spiral | spiral | spiral | spiral | spiral | spiral | spiral | spiral |
| groove β1 | Proportion of area | 98.0 | 100.0 | 100.0 | 100.0 | 100.0 | 100.0 | 100.0 | 100.0 | 95.0 | 100.0 |
| | having reference | | | | | | | | | | |
| | groove β1 formed | | | | | | | | | | |
| | relative to radius of | | | | | | | | | | |
| | polishing surface from | | | | | | | | | | |
| | center of polishing | | | | | | | | | | |
| | surface (%) | | | | | | | | | | |
| | Sectional shape | rectan- | Y-shape | Y-shape | Y-shape | Y-shape | Y-shape | Y-shape | Y-shape | rectan- | Y-shape |
| | | gular | | | | | | | | gular | |
| | Groove pitch P (mm) | 6.0 | 7.5 | 7.5 | 7.5 | 7.5 | 7.5 | 7.5 | 7.5 | 7.0 | 7.5 |
| | Groove width (mm) | 0.3 | 0.2 | 0.2 | 0.2 | 0.2 | 0.2 | 0.2 | 0.2 | 0.5 | 0.2 |
| | Depth (mm) | 1.5 | 1.3 | 1.5 | 1.5 | 1.3 | 1.3 | 1.3 | 1.3 | 1.2 | 1.3 |
| Grooves γ | Position of first end | 5.2 | 5.2 | 5.2 | 5.2 | 0.0 | 0.0 | 0.0 | 0.0 | 5.2 | 5.2 |
| | Eγ1 (%)*1 | | | | | | | | | | |
| | Position of second end | 51.6 | 51.6 | 51.6 | 51.6 | 51.6 | 51.6 | 51.6 | 51.6 | 51.6 | 51.6 |
| | Eγ2 (%)*1 | | | | | | | | | | |
| | Shape | straight | straight | straight | straight | straight | straight | straight | straight | straight | straight |
| | | line | line | line | line | line | line | line | line | line | line |
| | Sectional shape | rectan- | Y-shape | Y-shape | Y-shape | Y-shape | Y-shape | Y-shape | Y-shape | rectan- | Y-shape |
| | | gular | | | | | | | | gular | |
| | Groove width (mm) | 0.2 | 0.5 | 0.5 | 0.5 | 0.5 | 0.5 | 0.5 | 0.5 | 0.5 | 0.5 |
| | Depth (mm) | 1.5 | 1.5 | 1.3 | 1.3 | 1.5 | 1.3 | 1.3 | 1.3 | 1.2 | 1.5 |
| | Number | 16 | 8 | 8 | 8 | 8 | 8 | 8 | 8 | 16 | 8 |
| | Presence or absence of | pres- | pres- | pres- | pres- | pres- | pres- | pres- | pres- | pres- | pres- |
| | intersection with | ence | ence | ence | ence | ence | ence | ence | ence | ence | ence |
| | reference groove β1 | | | | | | | | | | |
| Ratio of depth of grooves α to depth | | 1.0 | 1.2 | 0.9 | 1.0 | 1.2 | 1.2 | 1.2 | 1.2 | 1.3 | 1.2 |
| of reference groove β1 | | | | | | | | | | | |
| Distance between first end Eα1 of | | 31.4 | 34.4 | 34.4 | 34.4 | 34.4 | 34.4 | 34.4 | 34.4 | 28.4 | 38.4 |
| grooves α and second end Eγ2 of | | | | | | | | | | | |
| grooves γ (%) *2 | | | | | | | | | | | |
| Ratio of length of grooves α to | | 25.9 | 21.6 | 21.6 | 21.6 | 19.4 | 19.4 | 19.4 | 19.4 | 21.6 | 19.4 |
| length of grooves γ (%) | | | | | | | | | | | |
| Evaluation | Polishing rate | 1250 | 1200 | 1153 | 1149 | 1191 | 1179 | 1179 | 1179 | 1180 | 1173 |
| results | (nm/min) | | | | | | | | | | |
| | Polishing uniformity | 1.5 | 1.8 | 3.0 | 3.2 | 2.1 | 2.3 | 2.3 | 2.3 | 1.4 | 1.9 |
| | (%) | | | | | | | | | | |
| | Polishing uniformity of | 1.8 | 1.9 | 3.5 | 3.8 | 2.5 | 3.0 | 3.0 | 3.0 | 1.6 | 2.0 |
| | edge area (%) | | | | | | | | | | |

| | | Example | | | | | | | | | |
|---|---|---|---|---|---|---|---|---|---|---|---|
| | | 11 | 12 | 13 | 14 | 15 | 16 | 17 | 18 | 19 | 20 |
| Grooves α | Position of first end | 86.6 | 85.0 | 96.0 | 75.0 | 78.0 | 79.0 | 87.0 | 93.0 | 83.0 | 71.0 |
| | Eα1 (%)*1 | | | | | | | | | | |
| | Position of second end | 99.7 | 98.0 | 99.0 | 88.0 | 93.0 | 86.0 | 98.0 | 96.0 | 95.0 | 95.0 |
| | Eα2 (%)*1 | | | | | | | | | | |
| | Shape | straight | straight | arc | straight | straight | straight | straight | straight | straight | straight |
| | | line | line | | line | line | line | line | line | line | line |
| | Sectional shape | Y-shape | Y-shape | rectan- | Y-shape | rectan- | rectan- | rectan- | rectan- | rectan- | rectan- |
| | | | | gular | | gular | gular | gular | gular | gular | gular |
| | Groove width (mm) | 0.2 | 0.2 | 0.3 | 0.5 | 0.3 | 0.3 | 0.5 | 0.5 | 0.4 | 0.5 |
| | Depth (mm) | 1.6 | 1.6 | 1.3 | 1.5 | 1.2 | 2.8 | 1.6 | 1.6 | 1.8 | 1.3 |
| | Number | 8 | 8 | 8 | 16 | 6 | 16 | 8 | 8 | 32 | 16 |
| | Presence or absence of | pres- | pres- | pres- | absence | pres- | pres- | pres- | pres- | pres- | pres- |
| | intersection with | ence | ence | ence | | ence | ence | ence | ence | ence | ence |
| | reference groove β1 | | | | | | | | | | |
| Reference | Shape | spiral | spiral | concentric | spiral | concentric | spiral | latticed | spiral | concentric | spiral |
| groove β1 | Proportion of area | 100.0 | 100.0 | 99.0 | 70.0 | 100.0 | 100.0 | 100.0 | 100.0 | 100.0 | 100.0 |
| | having reference | | | | | | | | | | |
| | groove β1 formed | | | | | | | | | | |
| | relative to radius of | | | | | | | | | | |
| | polishing surface from | | | | | | | | | | |
| | center of | | | | | | | | | | |
| | polishing surface (%) | | | | | | | | | | |
| | Sectional shape | Y-shape | Y-shape | rectan- | rectan- | rectan- | rectan- | rectan- | rectan- | rectan- | rectan- |
| | | | | gular | gular | gular | gular | gular | gular | gular | gular |
| | Groove pitch P (mm) | 7.5 | 7.5 | 6.0 | 7.0 | 6.0 | 6.0 | 10.0 | 4.5 | 3.0 | 6.0 |
| | Groove width (mm) | 0.2 | 0.2 | 0.3 | 0.5 | 0.3 | 0.5 | 0.5 | 0.5 | 0.5 | 0.5 |
| | Depth (mm) | 1.3 | 1.3 | 1.1 | 1.0 | 1.5 | 1.2 | 1.3 | 1.2 | 1.2 | 1.3 |
| Grooves γ | Position of first end | 5.2 | 5.2 | 5.2 | 5.2 | 5.2 | 5.2 | no | 5.2 | 5.2 | 5.2 |
| | Eγ1 (%)*1 | | | | | | | groove γ | | | |
| | Position of second end | 52.5 | 51.6 | 51.6 | 51.6 | 51.6 | 51.6 | | 68.4 | 61.9 | 61.9 |
| | Eγ2(%)*1 | | | | | | | | | | |
| | Shape | straight | straight | arc | straight | straight | straight | | straight | straight | straight |
| | | line | line | | line | line | line | | line | line | line |
| | Sectional shape | Y-shape | Y-shape | rectan- | rectan- | inversed | V-shape | | rectan- | rectan- | rectan- |
| | | | | gular | gular | trapezoid | | | gular | gular | gular |
| | Groove width (mm) | 0.5 | 0.5 | 0.4 | 0.5 | 0.3 | 0.6 | | 0.5 | 0.5 | 0.5 |
| | Depth (mm) | 1.5 | 1.5 | 1.1 | 1.2 | 1.5 | 1.2 | | 1.2 | 1.2 | 1.5 |
| | Number | 8 | 8 | 8 | 16 | 6 | 16 | | 8 | 32 | 16 |
| | Presence or absence of | pres- | pres- | pres- | pres- | pres- | pres- | | pres- | pres- | pres- |
| | intersection with | ence | ence | ence | ence | ence | ence | | ence | ence | ence |
| | reference groove β1 | | | | | | | | | | |
| Ratio of depth of grooves α to depth | | 1.2 | 1.2 | 1.2 | 1.5 | 0.8 | 2.3 | 1.2 | 1.3 | 1.5 | 1.0 |
| of reference groove β1 | | | | | | | | | | | |
| Distance between first end Eα1 of | | 34.1 | 33.4 | 44.4 | 23.4 | 26.4 | 27.4 | — | 24.6 | 21.1 | 9.1 |
| grooves α and second end Eγ2 of | | | | | | | | | | | |
| grooves γ (%) *2 | | | | | | | | | | | |
| Ratio of length of grooves α to | | 27.7 | 28.0 | 6.5 | 28.0 | 32.3 | 15.1 | — | 4.7 | 21.2 | 42.3 |
| length of grooves γ (%) | | | | | | | | | | | |
| Evaluation | Polishing rate | 1179 | 1182 | 1135 | 1020 | 1168 | 1138 | 1150 | 1142 | 1015 | 1005 |
| results | (nm/min) | | | | | | | | | | |
| | Polishing uniformity | 1.8 | 1.7 | 3.5 | 3.0 | 2.8 | 2.3 | 2.0 | 3.4 | 3.0 | 3.5 |
| | (%) | | | | | | | | | | |
| | Polishing uniformity of | 2.1 | 1.8 | 3.8 | 3.5 | 3.2 | 2.6 | 2.1 | 3.8 | 3.4 | 3.9 |
| | edge area (%) | | | | | | | | | | |

| | | Comparative Example | | | |
|---|---|---|---|---|---|
| | | 1 | 2 | 3 | 4 |
| Grooves α | Position of first end | 72.0 | no groove α | 50.0 | 60.0 |
| | Eα1 (%)*1 | | | | |
| | Position of second end | 100.0 | | 65.0 | 90.0 |
| | Eα2 (%)*1 | | | | |
| | Shape | straight line | | straight line | straight line |
| | Sectional shape | rectangular | | rectangular | rectangular |
| | Groove width (mm) | 0.5 | | 0.5 | 0.3 |
| | Depth (mm) | 1.3 | | 1.2 | 1.2 |
| | Number | 16 | | 8 | 16 |
| | Presence or absence of | presence | | presence | presence |
| | intersection with | | | | |
| | reference groove β1 | | | | |
| Reference | Shape | spiral | spiral | concentric | concentric |
| groove β1 | Proportion of area | 100.0 | 100.0 | 95.0 | 98.0 |
| | having reference | | | | |
| | groove β1 formed | | | | |
| | relative to radius of | | | | |
| | polishing surface from | | | | |
| | center of polishing | | | | |
| | surface (%) | | | | |
| | Sectional shape | Y-shape | Y-shape | rectangular | rectangular |
| | Groove pitch P (mm) | 7.0 | 7.0 | 6.0 | 3.0 |
| | Groove width (mm) | 0.5 | 0.2 | 0.5 | 0.3 |
| | Depth (mm) | 1.3 | 1.3 | 1.2 | 1.0 |
| Grooves γ | Position of first end | 5.2 | 5.2 | 3.9 | 5.2 |
| | Eγ1 (%)*1 | | | | |
| | Position of second end | 51.6 | 51.6 | 38.7 | 51.6 |
| | Eγ2 (%)*1 | | | | |
| | Shape | straight line | straight line | straight line | straight line |
| | Sectional shape | rectangular | Y-shape | rectangular | rectangular |
| | Groove width (mm) | 0.5 | 0.5 | 0.5 | 0.3 |
| | Depth (mm) | 1.3 | 1.5 | 1.3 | 1.2 |
| | Number | 16 | 8 | 8 | 16 |
| | Presence or absence of | presence | presence | presence | presence |
| | intersection with | | | | |
| | reference groove β1 | | | | |
| Ratio of depth of grooves α to depth | | 1.0 | — | 1.0 | 1.2 |
| of reference groove β1 | | | | | |
| Distance between first end Eα1 of | | 20.4 | — | 11.3 | 8.4 |
| grooves α and second end Eγ2 of | | | | | |
| grooves γ (%) *2 | | | | | |
| Ratio of length of grooves α to | | 60.3 | — | 43.1 | 64.7 |
| length of grooves γ (%) | | | | | |
| Evaluation | Polishing rate | 953 | 990 | 970 | 965 |
| results | (nm/min) | | | | |
| | Polishing uniformity | 5.8 | 4.3 | 6.2 | 5.0 |
| | (%) | | | | |
| | Polishing uniformity of | 7.1 | 6.2 | 9.5 | 8.2 |
| | edge area (%) | | | | |

*1The distance from the center of the polishing surface is represented by the ratio relative to the radius of the polishing surface.
*2 It means the difference between the distance A from the center of the polishing surface to the first end Eα1 of a groove α and the distance B from the center of the polishing surface to the second end Eγ2 of a groove γ [distance A − distance B].

As is apparent from the results in Table 1, the polishing pads of Examples 1 to 20 of this embodiment achieve both the polishing rate and the polishing uniformity in an edge area in a high level. On the other hand, the polishing pads of Comparative Examples 1 to 4 ware inferior in at least one of the polishing rate and the polishing uniformity in an edge area.

### REFERENCE SIGNS LIST

1: Polishing layer
6: Adhesive layer
7: Cushion layer
10, 20: Polishing pad
50: Material to be polished
60: Slurry
100: CMP Apparatus
101: Rotary fixed plate
102: Slurry supply nozzle
103: Polishing head
104: Pad conditioner
105: Head main body
106: Retainer ring
107: Elastic membrane
108: Air chamber
α: Groove α
γ: Groove γ
H: Spiral groove
Eα1: First end of groove α
Eα2: Second end of groove α
Eγ1: First end of groove γ
Eγ2: Second end of groove γ
F: Polishing surface
G: Center of polishing surface
P: Pitch
R: Radius of polishing surface
S: Angle
W: Groove width
Wr: Width of retainer ring

1. A polishing pad comprising a polishing layer having a circular polishing surface,
the polishing layer having at least one groove α that has a first end Eα1 and a second end Eα2 which is closer to an outer circumference of the polishing surface than the first end Eα1 is and that extends from the first end Eα1 toward the second end Eα2,
the first end Eα1 of the groove α being present in an area (1) that is a range of 70.0 to 99.0% relative to a radius of the polishing surface from a center of the polishing surface,
the second end Eα2 of the groove α being not connected to the outer circumference of the polishing layer.

2. The polishing pad according to claim 1, wherein the first end Eα1 of the groove α is present in an area of 70.0 to 95.0% relative to the radius of the polishing surface from the center of the polishing surface.

3. The polishing pad according to claim 1, wherein the second end Eα2 of the groove α is present in an area of 85.0 to 99.9% relative to the radius of the polishing surface from the center of the polishing surface.

4. The polishing pad according to claim 1, wherein a number of the grooves α is 2 to 36.

5. The polishing pad according to claim 1, wherein the groove α has a linear shape.

6. The polishing pad according to claim 1, wherein the polishing layer further has a reference recess β,
the reference recess β being a spiral, annular, or latticed reference groove β1 or reference holes β2 including a plurality holes.

7. The polishing pad according to claim 6, wherein the polishing layer has the reference groove β1 and the groove α intersects the reference groove β1 at least at one point.

8. The polishing pad according to claim 6, wherein the groove α has a depth that is 0.5 to 2.5 times a depth of the reference groove β1.

9. The polishing pad according to claim 1, wherein the polishing layer further has at least one groove γ that has a first end Eγ1 and a second end Eγ2 which is closer to the outer circumference of the polishing surface than the first end Eγ1 is and that extends from the first end Eγ1 toward the second end Eγ2,
the first end Eγ1 of the groove γ being present in an area (2) that is a range of less than 70.0% relative to the radius of the polishing surface from the center of the polishing surface.

10. The polishing pad according to claim 9, wherein the first end Eα1 of the groove α is closer to the outer circumference of the polishing surface than the second end Eγ2 of the groove γ is.

11. The polishing pad according to claim 10, wherein a difference between a distance A from the center of the polishing surface to the first end Eα1 of the groove α and a distance B from the center of the polishing surface to the second end Eγ2 of the groove γ [distance A−distance B] is 8.0 to 50.0% relative to the radius of the polishing surface.

12. The polishing pad according to claim 9, wherein a length of the groove α is 5.0 to 100.0% relative to a length of the groove γ.

13. The polishing pad according to claim 9, wherein at least one of the groove α and the groove γ has a linear shape.

14. A polishing method comprising polishing a material to be polished by using the polishing pad according to claim 1, the groove α being disposed under a retainer ring that surrounds the material to be polished.

15. A method for producing a semiconductor, the method comprising a step of polishing a semiconductor material by the polishing method according to claim 14.
